(19) United States
(12) Patent Application Publication
(10) Pub. No.: US 2008/0204068 A1
(43) Pub. Date: Aug. 28, 2008

(54) METHOD FOR ESTIMATING DEFECTS IN AN NPN TRANSISTOR ARRAY

(75) Inventors: Erik M. Dahlstrom, Burlington, VT (US); Benjamin T. Voegeli, Burlington, VT (US); Thomas W. Weeks, Morrisville, VT (US)

Correspondence Address: SCULLY, SCOTT, MURPHY & PRESSER, P.C., 400 GARDEN CITY PLAZA, Suite 300, GARDEN CITY, NY, 11530, US

(73) Assignee: International Business Machines Corporation, Armonk, NY (US)

(21) Appl. No.: 11/680,283

(22) Filed: Feb. 28, 2007

(51) Int. Cl. G01R 31/26

(52) U.S. Cl. 324/768; 702/58

(57) ABSTRACT

A method for testing bipolar transistors in an integrated circuit includes first measuring first conductances of leakage paths between collectors and emitters of a first plurality of bipolar transistors with a known number of defects, calculating a per defect conductance value using the measured first conductances and the known number of defects to derive the linear relation. The method then measures second conductances of leakage path between collectors and emitters of a second plurality of bipolar transistors under test and having an unknown number of defects. Using the measured leakage path current from the second conductances and the linear relation, the number of defects related to the second plurality of bipolar transistors under test may be accurately determined.

### BACKGROUND OF THE INVENTION

The invention relates to defect testing of semiconductor integrated circuits (ICs) and, more particularly, relates to an IC test method by which defects causing current leakage during IC testing are better qualified and accounted for though the use of leveraging test data derived from prior testing of similar ICs.

Presently evolving semiconductor integrated circuit techmology is achieving higher levels of integration so that tens of thousands of circuits are being fabricated on a single semiconductor chip. Because of the high-density packing, the presence of micro-defects such as precipitates, dislocations, stacking faults, etc., are known to influence yield, performance and reliability of the semiconductor device. In particular, the aforementioned defects are known to cause what are known as “pipes,” or pipe defects, the presence of which may cause shorts or unwanted conductive paths between emitter and collector, lower voltage breakdowns, soft junctions, non-uniform doping, resistivity variations, etc. Transistor parameters such as gain, leakage current and saturation voltage are influenced by the numbers of pipe defects. In NPN transistors, pipe defects appear as N-type regions extending from the N emitter region, reaching the N collector region through the p-type base region. Such pipe defects result in a leakage current Ic when the device should be turned OFF. A more detailed description of pipe defects in semiconductor fabrication, and fabrication techniques for minimizing such defects may be found in U.S. Pat. No. 4,069,068, and U.S. Pat. No. 4,110,125, both commonly owned.

At IBM, semiconductor professionals are known to monitor leakage current in heterojunction bipolar transistor production, particularly in parallel-chain NPN devices for use in integrated circuit testing, One technique (“light-up” technique) includes destructive testing, wherein wafer areas under test are illuminated and the number and location of the defects may be estimated by photon emission associated with the defect when the transistors are biased in the sub-threshold region. That is, where the light generates a leakage current through a pipe defect, a thermal camera picks up the effect of the leaked current. The known light-up technique, however, is limited due to its destructive nature, and the limited data acquired.

Detection of one defect in one transistor within a chain of 1000 transistors, or 10,000 transistors should not require that the semiconductor IC be discarded. A single defect may be caused by quite another problem than a case where 30 or 100 defects are found in a similarly sized chain (and IC). Conventional non-destructive techniques for production testing, however, merely qualify testing results as simply pass/fail. They are not known distinguish an IC with one transistor fail from an IC with 30 or 100 transistor fails. In particular, NPN devices are “failed” using conventional non-destructive testing techniques where currents detected are overly high. But little specific information is obtained about the actual number of defects relating to overly high detected current using conventional testing techniques. By better characterizing defects, e.g., pipe defects, and their numbers within an IC under production testing, test procedure utility may be extended to better qualify failures. By better qualifying failures, the IC may be better qualified such that some wafers may be used for some purposes rather than merely discarded, as the case using conventional related testing.

### SUMMARY OF THE INVENTION

The present invention provides an improved method for testing and characterizing defects in NPN BJTs and HBTs based on a linear relationship derived from prior testing of similarly manufactured integrated circuits having a known number of defects. The prior testing qualifies the number of known defects and the sub-threshold collector currents in the known BJTs and HBTs, and deriving the linear relationship therefrom. The novel testing method requires grounding the emitter and fixing the collector and base potential in the sub threshold region to obtain the conductance or resistance of the NPN device under production test. Potentials at the sub threshold regions are well below those potentials that tend to precipitate an onset of avalanching. Through use of the known linear relation, known number of defects and the acquired resistance/conductance of the similar IC under test results, defects in the IC under test may be relatively accurately estimated and characterized. That is, by knowing resistances at particular testing potentials in an IC under test, the number of defects in the IC may be reliably projected using the known linear relation derived from the known prior tested IC and the linear relation derived by said prior testing. The defect projection data derived by the inventive method allows for a more detailed understanding of the inherent nature of the IC under test (production IC). A more detailed understanding of the IC under test may allow that ICs that would be normally discarded in view of conventional test results may be used nevertheless for particular applications.

In one embodiment, the invention comprises a method for testing bipolar transistors in an integrated circuit (IC) using a known linear relation derived from test measurement data from prior testing of similar bipolar transistors. By use of the linear relation, and a detected current in the IC under test, a number of defects may be accurately estimated to qualify the defects in the IC under test. The method includes measuring a first conductance of a leakage path between a collector and emitter of a first plurality of bipolar transistors having a known number of defects, and calculating a per defect conductance value and deriving the linear relation. With the linear relation, the method then measures a second conductance of a leakage path between a collector and emitter of a second plurality of bipolar transistors under test, having an unknown number of defects. The second conductances and the linear relation provides for determining substantially the number of defects related to the second plurality and characterizing those defects and the IC thereby.

### DESCRIPTION OF THE DRAWING FIGURES

FIGS. 1a, 1b, 1c and 1d are a collection of I-V plots or characteristic curves of one or more transistors taken under test to illustrate the fundamental biasing, testing and defect qualification of the invention herein; and

FIG. 2 is a flow block diagram depicting a method of the invention.

### DETAILED DESCRIPTION OF THE INVENTION

The inventive method includes the use of a known linear relation of defect conductance values derived from testing a first IC (with known defects) to determine or estimate a number of defects in a second IC under production testing (with an unknown number of defects) by using the result testing conductance paths between collector and emitter in the second IC. For example, the first number of transistors may comprise a chain of 2000, or 20,000 transistors, or a plurality of such chains built into a semiconductor wafer or IC. Destructively testing the first number of transistors may be required to acquire the resistance or conduction path data, and the number of defected transistors, to calculate the linear relationship of the per defect conductance. By knowing the linear relation between numbers of defects, e.g., pipe defect density, the number and severity of defects may be accurately estimated in production ICs under test by determining the conductance or leakage current during the production testing. That is, using the known data and linear relation, defects may be estimated by measuring the production IC's base to emitter currents and using the known linear relation to estimate the severity and/or number of defects in the production IC under test. Accurately estimating or determining the number and character of defects in the production IC provides for an understanding of the impact, or lack of impact, the defects could have on a customer design.

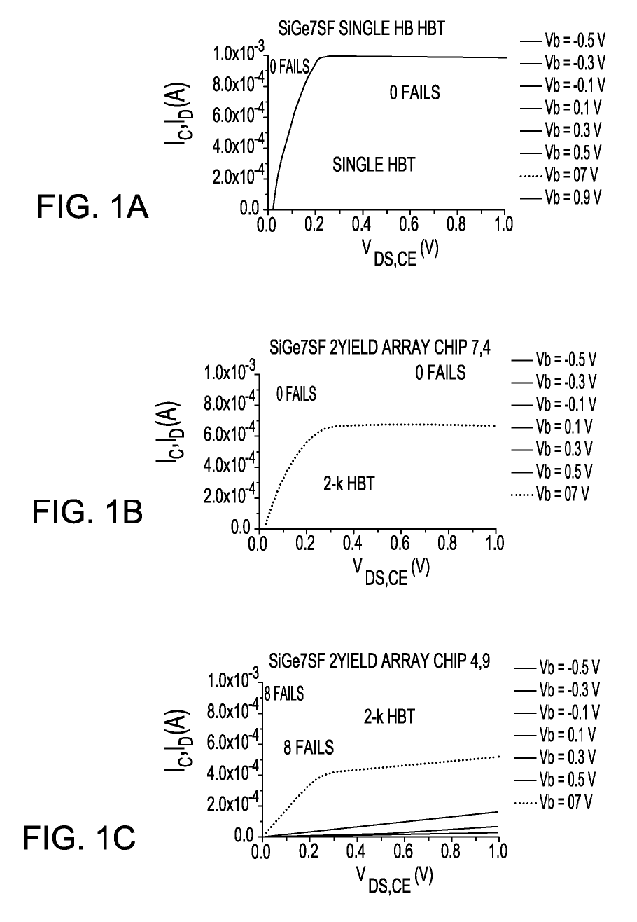

To better understand the invention, the reader's attention is directed to a set of four (4) figures depicting current voltage (I-V) characteristic curves from testing in accord with the inventive method. That is, FIG. 1a is an I-V characteristic curve for a single HBT device biased as its emitter is grounded; FIG. 1b is an I-V characteristic curve of a chain of 2000 transistors in which all emitters are grounded; FIG. 1c, and 1d are I-V characteristic curves of different 2000 transistor chains that are emitter-grounded. The linear relation to such transistor (FIG. 1a) or sets of transistors (FIGS. 1b, 1c and 1d) is known from the results of a related IC test process, such as the IBM “light-up” process previously discussed. The known defect data and the linear relation derived from the known data are used in the inventive method to better understand fail signatures such as depicted in the FIGS. 1c and 1d plots. Knowing the fail signatures provides for knowing the severity of defects in the 2000-transistor HBT chains (where the number of defects is not known) and the related impact that those projected defects on the tested IC.

As mentioned, the emitter(s) is/are grounded during the testing, and the collectors swept from 0 to 1.5 V, which is below BVCEO of 2 V for this specific device type. The reader should note that BVCEO varies with device type so that BVCEO is chosen for a specific device type. Concurrently, the base is swept from −0.5 V to +0.9 V. The FIG. 1a I-V plot depicts the test results for a single HBT without defects. The FIG. 1a plot evidences that no conductance was detected or indicated but for the curve in which Vb=0.9 V, which corresponds to where NPN device has turned on (no defects). Like FIG. 1a, FIG. 1b shows no defect. That is, FIG. 1b depicts I-V curves for a parallel chain of about 2000 HBT devices with no defects evidenced by the I-V curve's absence of conductance except where Vb=0.7 V (biasing the chain to the “ON” state). FIGS. 1c and 1d, however, illustrate the I-V characteristics curves or test results for two different 2000-transistor chains of HBTs that have different numbers of defects. Thie chains were tested with their base voltages modulated in the sub turn-on region. Base emitter bias of VBE<0.7 V is a typical bias for “ON” operation for many class III-V or Si/SiGe bipolar transistors. The reader and the skilled artisan alilce should understand that the emitter-collector conductance of an NPN transistor with is V_{BE} biased below its turn-on voltage is approximately or practically zero (0). Hence the existence of pipe defects dramatically increases this conductance, or, emitter-collector leakage.

From the slope of these I-V curves (FIGS. 1c and 1d), a conductance or resistance is estimated, and a conductance or resistance per defect may be calculated. That is, the conductance per defect is derived from FIGS. 1c and 1d curves by simply dividing the inverse d (Ic(Vce))/dIc) by the number of defects N. The results are clearly linear. By using the relation between the resistance and the base potential, the number of fails N is readily estimated. It follows that by proper but not critical selection of bias parameters, NPN transistors can be through-tested at two bias points to estimate the number of defects in a chain of devices using the resistance R and the linear relation. Doing so improves yield control in that defective chips are not necessarily “conventionally” defective. That is, not all defective chips need be disposed of. By having a better understanding of the defects comprising a particular tested IC, and knowing their number and location, some wafers with like defects may be nevertheless useable for a customer's needs.

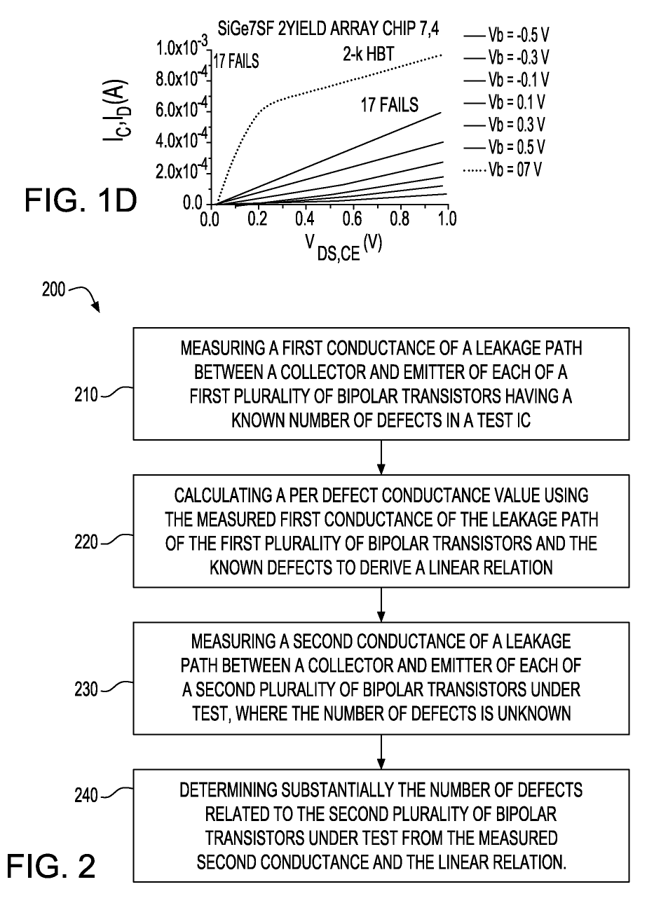

FIG. 2 is a flow block diagram depicting the steps for carrying a method for testing 200 of the invention, where such linear relation may be used. The method tests bipolar transistors in an IC using the known linear relation. Block 210 represents a step of measuring first conductance values of leakage paths between collectors and emitters of a first plurality of bipolar transistors having a known number of defects. Block 220 represents a step of calculating a per defect conductance value using the measured first conductance values of the leakage paths and the known number of defects, and deriving the linear relation between conductance and defects therefrom. Block 230 represents a step of measuring second conductances of leakage paths between collectors and emitters of a second plurality of bipolar transistors under test, with an unknown number of defects. Block 240 represents a step of determining substantially the number of defects related to the second plurality of bipolar transistors under test from the measured second conductance and a calculated conductance value per defect derived from the linear relation. Knowing and characterizing the defects in the IC under test can provide for using partially defective ICs for particular purposes instead of merely discarding such defective ICs.

Although a few examples of the present invention have been shown and described, it would be appreciated by those skilled in the art that changes may be made in these embodiments without departing from the principles and spirit of the invention, the scope of which is defined in the claims and their equivalents.

1. A method for testing bipolar transistors in an integrated circuit (IC) under test using a known linear relation to determine a number of physical defects in the transistors and qualifying the defects, comprising the steps of:
measuring a first conductance of a leakage path between a collector and emitter of each of a first plurality of bipolar transistors comprising a test IC with a known number of defects;
calculating a per defect conductance value for the test IC using the measured first conductances and the known number of defects, and deriving a linear relation of conductance/defect therefrom;
measuring a second conductance of a leakage path between a collector and emitter of each of a second plurality of bipolar transistors comprising a production IC under test having an unknown number of defects; and
determining substantially the number of defects related to the second plurality of bipolar transistors in the production IC from the measured second conductances and the linear relation.

2. The method for testing as set forth in claim 1, wherein the defects are a class of defects referred to as pipe defects.

3. The method for testing as set forth in claim 1, wherein the steps of measuring the first conductances and calculating the per defect conductance values may be substituted for a single step of providing the derived linear relationship for the known number of defects.

4. The method for testing as set forth in claim 1, further including a step of selectively passing the IC under test where the number of defects and character of the defects are estimated to be acceptable for particular post-testing applications.

5. The method of testing as set forth in claim 4, wherein the step of selectively passing includes deducing a defect density rather than merely qualifying the integrated circuit as a pass/fail.

6. The method for testing as set forth in claim 1, wherein the steps of measuring the first conductances, and calculating the per defect conductance value are carried out using a light-up technique in which the number of light-ups is correlated with resistance.

7. The method for testing as set forth in claim 6, wherein the extracted resistance is derived from sub-threshold current and the number of light-ups.

8. The method of testing as set forth in claim 1, wherein the step of measuring the second conductances includes modulating the base conductivity by modulating the base bias with grounded emitter.

9. A computer readable medium that contains a plurality of computer readable instructions, which computer readable instructions are executable by a processor to carry out a method for testing bipolar transistors in a first integrated circuit using a known linear relation to determine a number of physical defects in transistors comprising a second integrated circuit under test, and to qualify the defects and the second integrated circuit under test using the linear relation, comprising the steps of:
measuring a first conductance of a leakage path between a collector and emitter of each of a first plurality of bipolar transistors comprising a test IC with a known number of defects;
calculating a per defect conductance value for the test IC using the measured first conductances and the known number of defects, and deriving a linear relation of conductance/defect therefrom;
measuring a second conductance of a leakage path between a collector and emitter of each of a second plurality of bipolar transistors comprising a production IC under test having an unknown number of defects; and
determining substantially the number of defects related to the second plurality of bipolar transistors in the production IC from the measured second conductances and the linear relation.
